(19) United States
(12) Patent Application Publication
(10) Pub. No.: US 2008/0084335 A1
(43) Pub. Date: Apr. 10, 2008

(54) APPARATUS AND METHOD FOR INPUTTING CHARACTERS IN PORTABLE TERMINAL

(75) Inventor: Wei WANG, Suwon-si (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/867,461

(22) Filed: Oct. 4, 2007

(30) Foreign Application Priority Data
Oct. 4, 2006 (KR) 2006-0097538

(51) Int. Cl. H03M 11/00

(52) U.S. Cl. 341/22

(57) ABSTRACT

An apparatus and a method for inputting characters in a portable terminal and are provided. The apparatus comprises an input unit for sensing key input, including character keys for inputting characters and numbers, and a position fixation symbol key for sensing the input of position fixation symbols; a display unit for outputting the input characters and position fixation symbols; a symbol converter for converting the position fixation symbols into characters to output them to the display unit; and a character processing unit for making the symbol converter convert the position fixation symbols into characters while changing an input mode selecting the kind of character to be entered after a sentence including one kind of characters and the position fixation symbols are being input.

### PRIORITY

This application claims priority under 35 U.S.C. §119 to an application filed in the Korean Intellectual Property Office on Oct. 4, 2006 and assigned Serial No. 2006-97538, the contents of which are incorporated herein by reference.

### BACKGROUND OF THE INVENTION

1. Field of the Invention

The present invention relates generally to an apparatus and method for inputting characters in a portable terminal, and in particular, to an apparatus and a method of inputting characters that reduces the number of times an input mode is changed while inputting various kinds of characters, such as Korean, English and special characters in a portable terminal.

2. Description of the Related Art

Recently, portable terminals such as a mobile communication terminal and a Personal Digital Assistant (PDA) are widely used. The portable terminal is widely used for taking an image or a moving picture by a mounted digital camera, viewing satellite broadcasting, editing a document, playing a game, operating a navigation, listening to music, transmitting and receiving a short message and multimedia messages including taking an image or a moving picture, as well as, for making a phone call or managing a schedule.

Due to the development of the portable terminal, cases in which characters are input using the portable terminal increase. For example, the cases where characters are input using the portable terminal increase include cases in which a character message is written in, in which a schedule is input in order to manage the schedule, and in which, after taking a picture by a portable terminal with a digital camera, the name of the taken image is input.

FIG. 1 illustrates an output screen where a character message is written in a portable terminal. In cases where a commonly used character message is written in a common portable terminal, one or more kinds of characters are used. As shown in FIG. 1, two input modes of alphabet and special characters, such as a parenthesis, a period, and comma are used.

In cases where a character message has two or more kinds of characters, the input mode should be changed at the point when the kind of character to be input is changed. To avoid such an inconvenience, a method in which each kind of characters are input was proposed. However, in this method, after inputting one kind of character, when the next kind of characters are input, a cursor for inputting characters must be pressed a plurality of times to be positioned in the position where another kind of characters are to be input. This also brings about inconvenience.

Therefore, there is a need for an apparatus and method for inputting characters that limits the number of times the input mode is changed and also limits the number of times an input key is required to be pressed when various kinds of characters are inputted.

### SUMMARY OF THE INVENTION

An object of the present invention is to substantially solve at least the above problems and/or disadvantages and to provide at least the advantages below. Accordingly, an object of the present invention is to provide an apparatus and method for inputting characters in a portable terminal.

Another object of the present invention is to provide an apparatus and method for inputting characters, which are capable of reducing the number of times an input mode is changed when various kinds of characters are input into a portable terminal.

Still another object of the present invention is to provide an apparatus and method for converting position fixation symbols into different kinds of characters while changing an input mode after inputting one kind of characters and the position fixation symbols when various kinds of characters are input into a portable terminal.

Still another object of the present invention is to provide an apparatus and method for inputting various characters, in a portable terminal, such that the number of times an input mode is changed is reduced, by inputting position fixation symbols instead of inputting different kinds of characters and then changing an input mode to input the same kind of characters at one time.

Accordingly, one aspect of the present invention provides for an apparatus for inputting characters in a portable terminal includes an input unit for sensing a key input, including character keys for inputting characters and numbers and a position fixation symbol key for sensing the input of position fixation symbols; a display unit for outputting the input characters and position fixation symbols; a symbol converter for converting the position fixation symbols into characters to output them to the display unit; and a character processing unit which makes the symbol converter convert the position fixation symbols into characters while changing an input mode selecting the kind of character after a sentence including one kind of characters and the position fixation symbols being input.

In accordance with a second aspect of the present invention, there is provided a method for inputting characters in a portable terminal which includes a sentence having one kind of character and position fixation symbols being input; selecting the position fixation symbol that comes first; and when the input of the character into which the position fixation symbol is to be converted is detected, converting the selected position fixation symbol into the input character.

### BRIEF DESCRIPTION OF THE DRAWINGS

The above and other objects, features and advantages of the present invention will become more apparent from the following detailed description when taken in conjunction with the accompanying drawings in which:

FIG. 1 illustrates an output screen when a character message is written in a portable terminal;

FIG. 2 illustrates a structure of a portable terminal wherein characters can be input according to the present invention;

FIG. 3 is a flowchart illustrating a process of inputting characters using position fixation symbols in a portable terminal according to the present invention;

FIGS. 4A to 4D illustrate examples of output screens on which position fixation symbols are input and converted in a portable terminal according to the present invention; and

FIGS. 5A to 5C illustrate another examples of output screens on which position fixation symbols are input and converted in a portable terminal according to the present invention.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

The present invention provides a method and an apparatus for inputting characters in a portable terminal that reduces the number of times an input mode is changed for inputting various kinds of characters such as English and Korean and special characters.

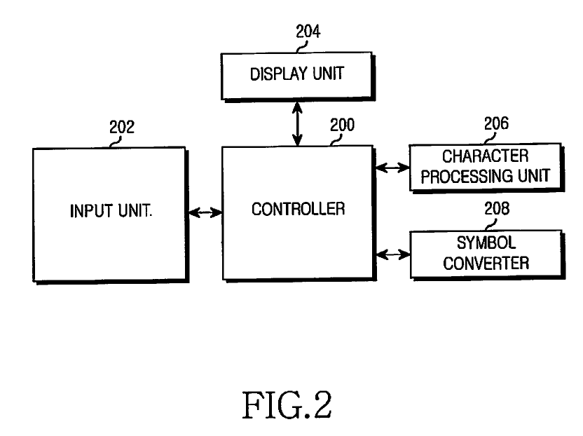

FIG. 2 illustrates a structure of portable terminal wherein characters can be input according to the present invention. Here, the portable terminal includes a controller 200, an input unit 202, a display unit 204, a character processing unit 206, and a symbol converter 208.

The input unit 202 includes a plurality of function keys such as character keys for inputting numbers and characters, a menu key, a cancellation key (deletion), a confirmation key, a telephone call key (TALK), a completion key (END), an Internet access key and navigation keys. The input unit also includes a position fixation symbol key, a next symbol selection key and a previous symbol selection key for changing a selection of symbol, to provide the controller 100 with the key input data corresponding to the key input by user.

In the input unit 202, the position fixation symbol key may be added or a character key may be used as the position fixation symbol key. Also, the next symbol selection key and the previous symbol selection key may be added, or navigation keys may be used as the next symbol selection key and the previous symbol selection key.

The display unit 204 displays the information state (or indicator) generated during the operation of the portable terminal, limited numbers and characters, and moving picture and still pictures. Moreover a color liquid crystal display (LCD) can be used as the display unit 202.

The character processing unit 206 outputs numbers or various kinds of characters and position fixation symbols which are input through the input unit 202 to the display unit 204, and makes the symbol converter 208 convert the input position fixation symbols into characters to output the characters.

The symbol converter 208 converts the position fixation symbols input through the input unit 202 into characters. The symbol converter 208 changes a selection of the position fixation symbol in accordance with the input of the next symbol selection key and the previous symbol selection key. The symbol converter 208 also converts the selected position fixation symbol into character when the character into which the position fixation symbol is to be converted is input. If the position fixation symbol is converted into a character, the symbol converter 208 automatically selects the next position fixation symbol.

The controller 200 controls the character processing unit 206 and the symbol converter 208. That is, the controller 200 can perform the function of the character processing unit 206 and the function of the symbol converter 208. According to the present invention, the character processing unit 206 and the symbol converter 208 are additionally structured in order to distinguish the functions of the character processing unit 206 and the symbol converter 208 from each other. Therefore, when a product is actually implemented, both functions of the character processing unit 206 and the symbol converter 208 can be processed in the controller 200, or one function thereof can be processed in the controller 200.

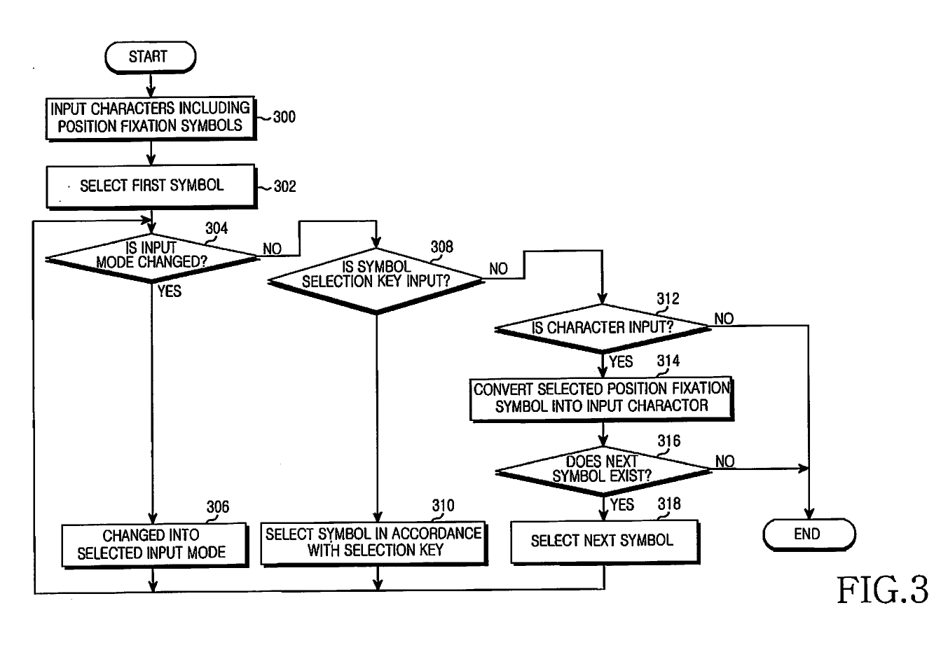

FIG. 3 is a flowchart illustrating the process of inputting characters using position fixation symbols in a portable terminal according to the present invention.

Referring to FIG. 3, in the step 300, characters, including position fixation symbols, are input. In the step 302, the position fixation symbol that comes first is then selected when the input of one kind of character is completed.

Then, the process goes to step 304 to detect whether an input mode has been changed, or proceeds to step 308 to detect whether a position fixation symbol to be converted has been selected, or proceeds to step 312 to repeatedly perform a conversion of the position fixation symbols into characters until the respective steps in which a character into which the symbol is to be converted is input, satisfies termination conditions.

In step 304, when a request to change an input mode, which selects the kind of character into which the position fixation symbol is to be converted, is sensed, the process goes to step 306 in which it is changed to the selected input mode.

In step 308, when the input of a next symbol selection key or previous symbol selection key for changing a selection of position fixation symbol is detected, the algorithm proceeds to step 310 in which a previous or next position fixation symbol corresponding to the input selection key is selected while skipping the characters between the position fixation symbol and the previous or next position fixation symbol.

In step 312, when the input of a character into which the position fixation symbol is to be converted is detected, the process goes to step 314 in which the selected position fixation symbol is converted into the input character. At this time, one position fixation symbol can be converted into a plurality of characters consisting of one kind of character.

Then, the process goes to step 316 where it is detected whether a next position fixation symbol exists. Here, the next position fixation symbol is the position fixation symbol that comes first and after the converted position fixation symbol. If there is no position fixation symbol after the converted position fixation symbol in the sentence, the next position fixation symbol is the first position fixation symbol in the sentence. In step 316, when it is determined that the next position fixation symbol exists, the goes to step 318 in which the next position fixation symbol is selected as a symbol to be converted.

However, when it is determined that the next position fixation symbol does not exist in step 316, the process is then terminated.

Also, when a key input for terminating a character input, or a key input which is not an input of changing an input mode in step 304, or a key input which is not an input of a symbol selection key in step 308, or a key input which is not an input of character into which the symbol is to be converted in step 312, is detected, the algorithm is terminated.

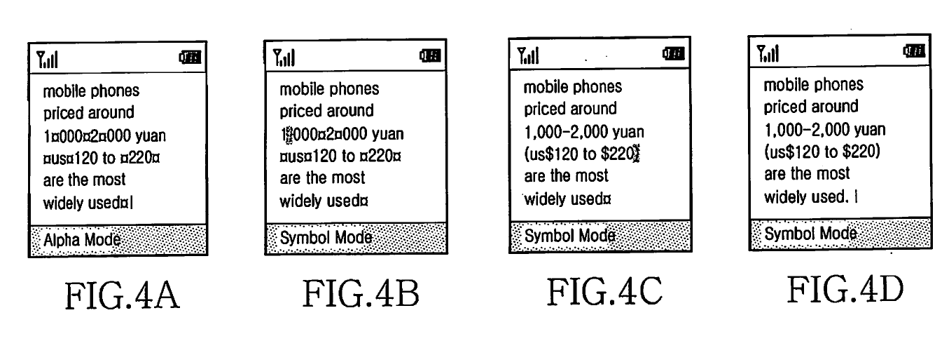

FIGS. 4A to 4D illustrate output screens on which position fixation symbols are input and converted in the portable terminal according to the present invention.

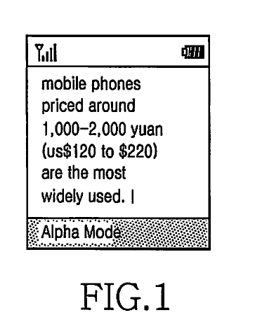

FIGS. 4A to 4D show output screens for a process of inputting characters using the position fixation symbol [symbol] when inputting a sentence shown in FIG. 1. FIG. 4A shows that in an English input mode, English characters are input and the position fixation symbols [symbol] are input in the positions where special characters are to be input without changing an input mode to a special character input mode. FIGS. 4B, 4C and 4D show the output screens that the position fixation symbol [symbol] is selected and converted while changing an input mode to a special character input mode.

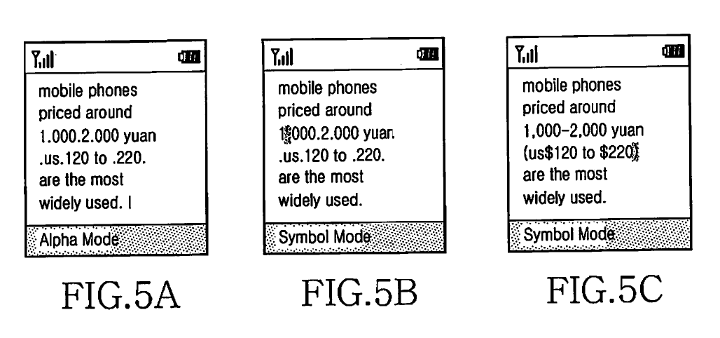

FIGS. 5A to 5C further illustrate output screens on which position fixation symbols are input and converted in the portable terminal according to the present invention.

FIGS. 5A to 5C are different from FIGS. 4A to 4D in that FIGS. 5A to 5C employ the position fixation symbol . (“period”). Thus, . (“period”), which is to be output as it is, is not converted.

In the apparatus for inputting characters in the portable terminal according to the present invention described with reference to FIGS. 3 to 5 and the method thereof, the position fixation symbol is selected one by one to be converted. However, in the portable terminal according to the present invention, the remaining position fixation symbols can be changed into desired characters, numbers, or special characters at one time.

As described above, according to the present invention, the apparatus for inputting one kind of characters and position fixation symbols and converting the position fixation symbols into different kinds of characters while changing an input mode when various kinds of characters are input in the portable terminal and the method thereof are provided. Therefore, it is possible to reduce the number of times of changing an input mode selecting the kind of character and the number of times of the key input.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An apparatus for inputting characters in a portable terminal, the apparatus comprising:
an input unit for sensing key input, including character keys for inputting characters and numbers and a position fixation symbol key for sensing the input of position fixation symbols;
a display unit for outputting the input characters and position fixation symbols;
a symbol converter for converting the position fixation symbols into characters to output them to the display unit; and
a character processing unit for making the symbol converter convert the position fixation symbols into characters while changing an input mode and selecting the kind of character after a sentence is input which includes one kind of character and the position fixation symbols being input.

2. The apparatus of claim 1, wherein the symbol converter converts a position fixation symbol and automatically selects a next position fixation symbol when position fixation symbols to be converted exist.

3. The apparatus of claim 1, wherein the input unit further comprises a next symbol selection key for selecting a next position fixation symbol and a previous symbol selection key for selecting a previous position fixation symbol, and the symbol converter selects the position fixation symbol corresponding to the input next symbol selection key or previous symbol selection key when the input of the next symbol selection key or the previous symbol selection key is sensed.

4. The apparatus of claim 1, wherein the position fixation symbol is a defined character informing of a position where a different kind of character will be inserted and is a special character, a period, or a comma.

5. A method of inputting character in a portable terminal, the method comprising the steps of:
inputting a sentence including one kind of character and position fixation symbols;
selecting the position fixation symbol that comes first; and
when the input of a character into which the position fixation symbol is to be converted is detected, converting the selected position fixation symbol into the input character.

6. The method of claim 5, further comprising when position fixation symbols to be converted exist, automatically selecting a next position fixation symbol, after converting the position fixation symbol into the character.

7. The method of claim 5, further comprising when an input mode request is made selecting the kind of character, changing an input mode into the requested input mode, after selecting the first position fixation symbol.

8. The method of claim 5, further comprising when it is detected the input of a next symbol selection key or previous symbol selection key for changing a selection of position fixation symbol, selecting the position fixation symbol corresponding to the input next symbol selection key or previous symbol selection key, before converting the position fixation symbol into the character.

9. The method of claim 5, wherein the position fixation symbol is a defined character informing of a position where a different kind of character will be inserted and is a special character, a period, or a comma.

10. A method of inputting characters in a portable terminal, the method comprising the steps of:
inputting a sentence including at least one position fixation symbol representing a kind of character which is different from at least one other kind of character in the sentence; and
converting the position fixation symbol into the kind of character.

11. The method of claim 10, wherein the position fixation symbol is a defined character informing of a position where the kind of character will be inserted.

12. A method of inputting characters in a portable terminal, the method comprising the steps of:
inputting a sentence including at least one position fixation symbol representing a kind of character which is different from at least one other kind of character in the sentence; and
when the input of a character into which the position fixation symbol is to be converted is detected, converting the selected position fixation symbol into the input character.

13. The method of claim 12, wherein the position fixation symbol is a defined character informing of a position where the kind of character will be inserted.

14. A portable terminal for inputting characters, comprising:
means for inputting a sentence including at least one position fixation symbol representing a kind of character which is different from at least one other kind of character in the sentence; and
means for converting the position fixation symbol into the kind of character.

15. The portable terminal of claim 14, wherein the position fixation symbol is a defined character informing of a position where the kind of character is to be inserted.
